(19) United States
(12) Patent Application Publication
(10) Pub. No.: US 2024/0272234 A1
(43) Pub. Date: Aug. 15, 2024

(54) DEGRADATION DETERMINATION METHOD FOR LFP CELL, DEGRADATION DETERMINATION DEVICE, AND VEHICLE INCLUDING THE DEVICE

(71) Applicant: TOYOTA JIDOSHA KABUSHIKI KAISHA, Toyota-shi (JP)

(72) Inventors: Osamu SHIMIZU, Komaki-shi (JP); Yoshimi HORIBE, Toyota-shi (JP)

(73) Assignee: TOYOTA JIDOSHA KABUSHIKI KAISHA, Toyota-shi (JP)

(21) Appl. No.: 18/503,548

(22) Filed: Nov. 7, 2023

(30) Foreign Application Priority Data
Feb. 15, 2023 (JP) 2023-021901

(51) Int. Cl. G01R 31/392; B60R 16/033; G01R 31/36; G01R 31/387

(52) U.S. Cl. CPC G01R 31/392; B60R 16/033; G01R 31/3648; G01R 31/387; B60L 58/16

(57) ABSTRACT

The controllers perform a series of charge/discharge processes in which LFP cell is charged to a full state of charge by the charger/discharger, LFP cell in a full state of charge is discharged by the charger/discharger until OCV of LFP cell reaches a predetermined OCV of LFP cell that uniquely represents the common capacity before and after the degradation of LFP cell, and the current integrated value of the discharge current is acquired during the discharge process. The controllers perform the charge/discharge process one or more times to obtain the variation capacity of LFP cell based on the one or more current integrated values obtained thereby. The controllers add the variation capacity to the common capacity, calculate the full charge capacity of LFP cell, and determine the degradation of LFP cell based on the calculated full charge capacity of LFP cell and the initial full charge capacity of LFP cell.

### CROSS-REFERENCE TO RELATED APPLICATION

This application claims priority to Japanese Patent Application No. 2023-021901 filed on Feb. 15, 2023, incorporated herein by reference in its entirety.

### BACKGROUND

### 1. Technical Field

The present disclosure relates to a degradation determination method for an LFP cell, a degradation determination device, and a vehicle including the device.

### 2. Description of Related Art

Conventionally, LFP (lithium iron phosphate ion) cells have been known. The LFP cell is a lithium-ion secondary battery in which lithium iron phosphate (LiFePO₄) is used as the material of a positive electrode. The LFP cell is mounted in a vehicle such as an engine-driven vehicle, a battery electric vehicle, or a hybrid electric vehicle, and is used as a power source for low-voltage use or a power source for high-voltage use (such as a power source for driving the vehicle).

Japanese Unexamined Patent Application Publication No. 2008-261669 (JP 2008-261669 A) discloses a method of detecting a full charge capacity of a battery. The method according to the document includes: detecting no-load voltages (first and second no-load voltages V_{OCV1}, V_{OCV2}) of a battery at two different timings (first and second no-load timings); acquiring remaining capacities (first and second remaining capacities SOC₁, SOC₂) of the battery corresponding to the first and second no-load voltages V_{OCV1}, V_{OCV2}; computing a remaining capacity variation rate (δS[%]) from the difference between the first and second remaining capacities SOC₁, SOC₂; computing a capacity variation value (δAh) of the battery from an integrated value of a charge/discharge current of the battery between the first and second no-load timings; and computing a full charge capacity (Ahf) of the battery from the remaining capacity variation rate (δS [%]) and the capacity variation value (δAh).

### SUMMARY

Degradation of a secondary battery is determined based on the proportion of the full charge capacity [Ah] at the time of degradation to the initial (pre-degradation) full charge capacity [Ah], for example. This is called State of Health (SOH), and it is indicated that the secondary battery is degraded to a greater degree as the SOH is lower. Since the initial full charge capacity of a secondary battery can be grasped in advance, the degree of degradation of the secondary battery can be acquired (the SOH of the secondary battery can be calculated) if the present full charge capacity of the secondary battery can be detected as in JP 2008-261669 A.

In the method according to JP 2008-261669 A, a State Of Charge (SOC) corresponding to an Open Circuit Voltage (OCV) of a battery is acquired, in order to detect the full charge capacity of the battery. This is called OCV method. In the OCV method, an SOC is estimated from a voltage value (OCV) of a secondary battery acquired by a voltage sensor using the correlation (SOC-OCV curve) between the OCV and the SOC of the secondary battery. In the method according to JP 2008-261669 A, two OCVs are detected, two SOCs are estimated from the OCVs, and a full charge capacity is detected based on the two SOCs.

However, the LFP cell has an SOC region in which the OCV is hardly varied even if the SOC is varied (an SOC region in which there is little correlation between the OCV and the SOC). Therefore, it is difficult to detect a full charge capacity for the LFP cell using a method such as JP 2008-261669 A (a method of detecting a full charge capacity by estimating a plurality of SOCs from a plurality of OCVs). Hence, there is a desire for a method of detecting a full charge capacity suitable for the LFP cell.

An object of the present disclosure is to determine degradation of an LFP cell by detecting a full charge capacity of the LFP cell.

The present disclosure provides a degradation determination device for an LFP cell, including: a charger/discharger that charges and discharges the LFP cell; and a controller that controls the charger/discharger.

The controller executes a series of charge/discharge processes in which the LFP cell is charged to a fully charged state using the charger/discharger, and the LFP cell in the fully charged state is discharged using the charger/discharger until an open circuit voltage (OCV) of the LFP cell reaches a predetermined OCV of the LFP cell, the predetermined OCV uniquely representing a common battery capacity before and after degradation of the LFP cell, and an integrated current value of a discharge current during such discharge is acquired. The controller executes the charge/discharge processes one or more times to acquire a variable battery capacity of the LFP cell based on one or more integrated current values acquired through the charge/discharge processes.
The controller calculates a full charge capacity of the LFP cell by adding the variable battery capacity to the common battery capacity.
The controller determines degradation of the LFP cell based on the calculated full charge capacity of the LFP cell and an initial full charge capacity of the LFP cell.
In the degradation determination device for an LFP cell according to the present disclosure,
the controller may execute the charge/discharge processes two or more times to acquire two or more integrated current values through the charge/discharge processes, and determine an average value of the two or more integrated current values as the variable battery capacity.

The present disclosure also provides a vehicle including the above degradation determination device for an LFP cell,

the controller executes the charge/discharge processes while the vehicle is parked, and charges the LFP cell from a main battery mounted on the vehicle and discharges a current from the LFP cell to a load mounted on the vehicle in the charge/discharge processes.

The present disclosure also provides a degradation determination method for an LFP cell, including

performing a charge/discharge process including charging the LFP cell to a fully charged state using a charger/discharger, and discharging the LFP cell in the fully charged state using the charger/discharger until an OCV of the LFP cell reaches a predetermined OCV of the LFP cell, the predetermined OCV uniquely representing a common battery capacity before and after degradation of the LFP cell, and acquiring an integrated current value of a discharge current during such discharge.
The degradation determination method also includes acquiring a variable battery capacity of the LFP cell based on one or more integrated current values acquired by performing the charge/discharge process one or more times;
calculating a full charge capacity of the LFP cell by adding the variable battery capacity to the common battery capacity; and
determining degradation of the LFP cell based on the calculated full charge capacity of the LFP cell and an initial full charge capacity of the LFP cell.

According to the present disclosure, it is possible to determine degradation of an LFP cell.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating a schematic configuration of a degradation determination device 12 according to an embodiment;

FIG. 2 is a flow chart showing a process performed by the controllers 20; and

FIG. 3 is a diagram illustrating an exemplary discharging curve of a LFP cell.

### DETAILED DESCRIPTION OF EMBODIMENTS

Hereinafter, embodiments of the present disclosure will be described with reference to the drawings. It should be noted that the present disclosure is not limited to the embodiments described herein. In all the drawings, the same elements are denoted by the same reference numerals, and redundant description is omitted.

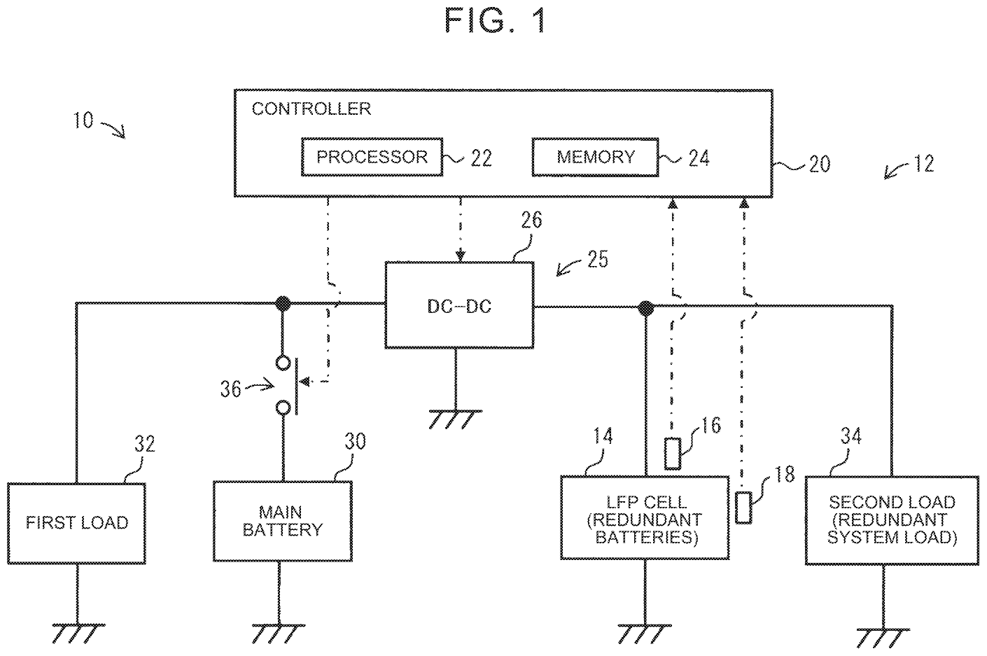

FIG. 1 is a diagram illustrating a schematic configuration of a degradation determination device 12 according to an embodiment. The degradation determination device 12 is mounted on the vehicle 10. The vehicle 10 is, for example, an engine-driven vehicle, a battery electric vehicle, hybrid electric vehicle, plug-in hybrid electric vehicle, or the like. The degradation determination device 12 determines deterioration of LFP cell 14 mounted on the vehicles 10.

LFP cell 14 is an assembled battery composed of one LFP cell (unit cell) or a plurality of LFP cells. In this embodiment, LFP cell 14 is used as a power source for low-voltage applications. In another embodiment, LFP cell 14 may be used as a power source for high-voltage applications, for example, as a power source for a vehicle-driven motor.

The vehicle 10 includes a first load 32, a main battery 30, a LFP cell 14, and a second load 34.

The first load 32 is a load to which electric power is constantly supplied regardless of whether the ignition switch of the vehicle 10 is turned on or off. The first load 32 includes an electronic device to which electric power is supplied during parking, and includes, for example, a drive recorder with a parking monitoring function. The parking monitoring function includes a function of recording the surroundings of the vehicle with a camera in order to prevent, for example, mischief, contact of an object with the parked vehicle, intrusion into the vehicle, and the like.

The main battery 30 is a secondary battery such as a lead storage battery. The main battery 30 supplies power to the first load 32. The main battery 30 supplies electric power to the second loads 34 and LFP cells 14 via DC-DC converters 26. The main battery 30 is charged by electric power from a generator (not shown) generated by the power of the engine. When the vehicle 10 is a battery electric vehicle or the like, the main battery 30 may be charged with electric power supplied from a high-voltage battery or the like for traveling the vehicle.

LFP cell 14 is redundantly provided as a sub-battery for backing up the main battery 30 when an abnormality occurs in the main battery 30. LFP cell 14 is configured to be capable of supplying electric power to the second loads 34.

The second load 34 is a load that is required to be supplied with power more stably than the first load 32. When an error occurs in the main battery 30, the second loads 34 can be continuously operated by electric power supplied from the back-up LFP cell 14. That is, the second load 34 is a load having a redundant power supply. The second loads 34 are, for example, electronic devices related to airbags, electronic devices related to Advanced Driver-Assistance System (ADAS), and the like.

The vehicle 10 includes a degradation determination device 12 for LFP cell 14. The degradation determination device 12 includes controllers 20, DC-DC converters 26, relays 36, current sensors 16, and voltage sensors 18.

The controller 20 includes a microcomputer. The controller 20 includes a processor 22 such as a CPU, a memory 24, and an input/output interface (not shown). The memory 24 is a random access memory (RAM), a read-only memory (ROM), a nonvolatile storage device (for example, a flash memory), or the like. The processor 22 implements various kinds of control and various functions described below by performing processes in accordance with programs and data stored in advance in a ROM or a non-volatile storage device by using a RAM. DC-DC converters 26, relays 36, current sensors 16, and voltage sensors 18 are electrically connected to the controllers 20. A signal indicating the state of the ignition switch of the vehicle 10 is input to the controller 20.

DC-DC converter 26 is a bi-directional DC-DC converter having a function of outputting the electric power of the main battery 30 to the second load 34 side and a function of outputting the electric power of LFP cell 14 to the first load 32 side. DC-DC converters 26 include a plurality of switching elements therein. The controllers 20 control DC-DC converters 26 by switching on/off the switching elements of DC-DC converters 26.

The relays 36 are arranged between the main battery 30 and DC-DC converters 26. The relay 36 is configured so that the opening/closing state is switched under the control of the controller 20.

The current sensor 16 is a device that detects a charge current and a discharge current of LFP cell 14. The detected value of the current sensor 16 is output to the controller 20. The voltage sensor 18 is a device that detects OCV (open-circuit voltage) of LFP cell 14. The detection value of the voltage sensor 18 is output to the controller 20.

In a typical vehicular state in which the degradation determination of LFP cell 14 is not performed, the controller 20 causes the relay 36 to be in the closed state to supply the electric power of the main battery 30 to the first load 32, and controls DC-DC converter 26 to supply the electric power of the main battery 30 to the second load 34.

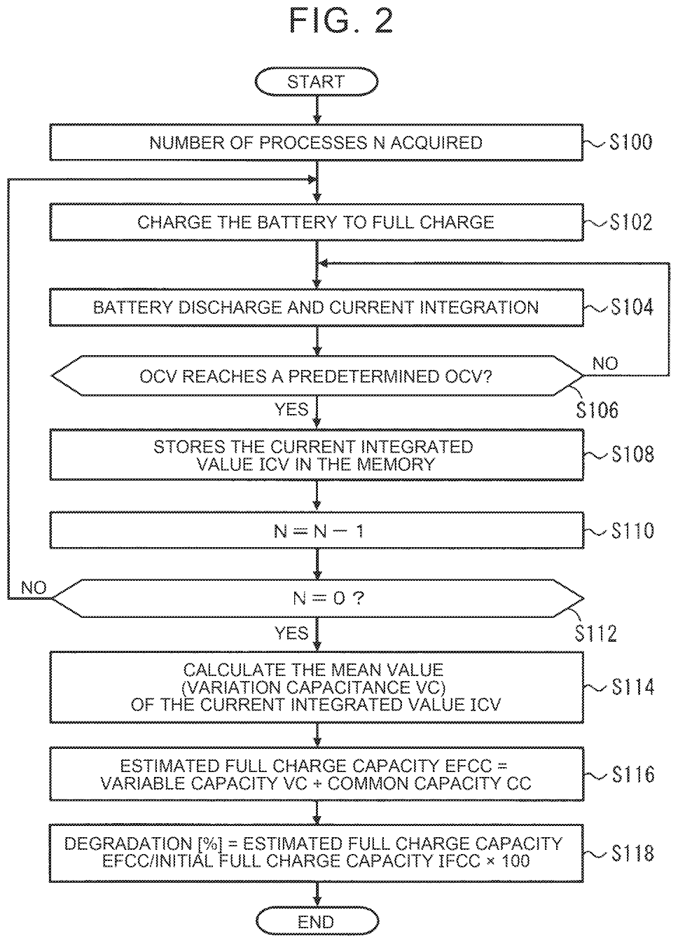

On the other hand, when the ignition switch of the vehicle 10 is in the off state, the controller 20 determines that the vehicle 10 is in the parking state, and performs a degradation determination process (FIG. 2) of LFP cell 14. In the degradation determination process, the controllers 20 charge (S102) and discharge (S104) LFP cells 14. When LFP cell 14 is charged (S102), the controller 20 closes the relays 36 and outputs the electric power of the main battery 30 to LFP cell 14 by controlling DC-DC converters 26. When discharging LFP cell 14 (S104), the controllers 20 open the relays 36 and control DC-DC converters 26 to provide the power of LFP cell 14 to the first loads 32. In the degradation determination process, DC-DC converters 26 and the relays 36 function as the charger/discharger 25 of LFP cells 14.

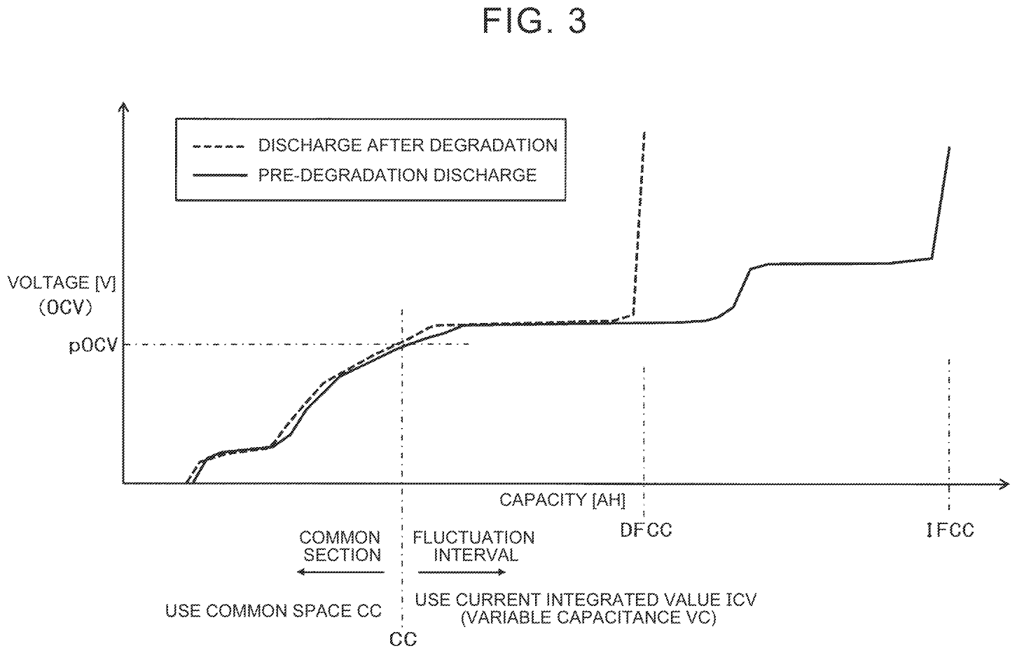

FIG. 2 is a flowchart illustrating a deterioration determination process performed by the controller 20. FIG. 3 is a graph illustrating an exemplary capacitance-OCV curve (discharge curve) when LFP cell 14 is discharged from a fully charged state. In FIG. 3, the horizontal axis represents battery capacity (charge amount) [Ah], and the vertical axis represents OCV [V]. In the drawing, a solid line represents a discharge curve of LFP cell at an early stage (prior to degradation), and a broken line represents a discharge curve of LFP cell after degradation. IFCC is the full charge capacity of the early LFP cell and DFCC is the full charge capacity of LFP cell after degradation. As shown in FIG. 3, DFCC is smaller than that of IFCC. LFP cell has a region in which the capacity (charge amount) is relatively large, and a region in which OCV hardly changes even when the capacity changes.

The flowchart of FIG. 2 will be described with reference to the graph of FIG. 3. When the controller 20 determines that the ignition switch of the vehicle 10 is in the off state and the vehicle 10 is in the parking state, the flow of FIG. 2 is started. In S100, the controllers 20 acquire the number-of-processes N. The number of processes N is the number of times the charge/discharge process (S108 from S102) described below is performed. N is an integer of 1 or more. N is stored in advance in the memory 24.

Next, in S102, the controller 20 outputs the electric power of the main battery 30 to LFP cell 14 by the charger/discharger 25, and charges LFP cell 14 to a fully charged condition. The controller 20 determines that LFP cell 14 is fully charged, for example, when the charging current detected by the current sensor 16 becomes equal to or less than a predetermined value.

In S104, the controllers 20 output the electric power of LFP cells 14 to the first loads 32 by the charger/discharger 25 to discharge LFP cells 14. At this time, the controllers 20 perform current integration of the discharging current to acquire the current integrated value ICV [Ah]. The current integrated value ICV [Ah] is calculated by the product of the current value [A] of the discharge current detected by the current sensor 16 and the discharge duration [h].

In S106, the controllers 20 check whether OCV of LFP cell 14 has reached a predetermined OCV (pOCV). OCV of LFP cell 14 is detected by the voltage sensor 18.

Here, as shown in FIG. 3, the predetermined OCV (pOCV) is OCV of LFP cell that uniquely represents the same capacity (also referred to as a common capacity CC or a common battery capacity CC) before and after degradation of LFP cell. As shown in FIG. 3, it is estimated that the capacity of LFP cell is a common capacity CC when OCV of LFP cell reaches the predetermined OCV (pOCV), regardless of whether or not the LFP cell is deteriorated. The predetermined OCV (pOCV) and the common capacity CC can be acquired in advance by experimentation or the like, and are stored in advance in the memories 24.

When S106 is No, the controller 20 continues discharging S104 (LFP cell 14 and acquiring the current integrated value ICV) until OCV of LFP cell 14 reaches a predetermined OCV (pOCV).

If S106 is turned Yes, the controllers 20 proceed to S108. In S108, the controllers 20 store the current integrated value ICV in the memories 24. Thus, the first charging and discharging process is completed.

In S110, the controllers 20 Decemberrement the number of processes N, and confirm whether the number of processes N becomes 0 (S112). When the number of processes N is not 0 (S112:No), the controller 20 returns to S102 and executes the charging/discharging process (S108 from S102). In this way, the controllers 20 repeatedly execute the charging/discharging process by the number of times of the number of processes N acquired by S100.

When S112 becomes Yes (when the number of processes N becomes 0), the controller 20 proceeds to S114. In S114, the controllers 20 read the current integrated value ICV from the memories 24, and acquire the variation capacity VC (also referred to as the variation battery capacity VC) of LFP cell based on the current integrated value ICV. Specifically, when the charging and discharging process is executed only once, the controllers 20 set the integrated current integrated value ICV as the variation capacity VC as it is. When the charging and discharging process is executed two or more times, the controllers 20 calculate an average value of the current integrated value IVC acquired in the respective charging and discharging processes, and set the average value as the variation capacity VC.

Next, in S116, the controllers 20 add the variation capacity VC to the common capacity CC to calculate the estimated full charge capacitance EFCC [Ah] of LFP cell 14].

Then, in S118, the controllers 20 determine the degradation of LFP cells 14 based on the estimated full charge capacity EFCC [Ah] of LFP cells 14 and the initial full charge capacity IFCC [Ah] of LFP cells 14. Specifically, the controllers 20 calculate the ratio of the estimated full charge capacity EFCC to the initial full charge capacity IFCC ((EFCC/IFCC)×100), and obtain the degradation degree [%] of LFP cell 14. IFCC of the full charge capacity of LFP cell 14 is stored in advance in the memories 24.

According to the embodiment described above, it is possible to estimate the full charge capacity of LFP cell 14 and determine the degradation of LFP cell 14.

Next, a modification will be described. In the embodiment described above, the main battery 30 for charging LFP cell 14 in the degradation determination process is a lead-acid battery. However, the main battery may be a high-voltage battery or the like that supplies electric power to the vehicle traveling motor. Further, the discharging of LFP cell in the deterioration determination process may be performed on a load other than the first load 32 mounted on the vehicle.

In addition, the above-described embodiments determine degradation of LFP cells mounted on vehicles. However, LFP cell may be removed from the vehicle, and the degradation determination process of LFP cell may be performed in an area outside the vehicle. In addition, the degradation determination process may be performed on LFP cells used for applications other than vehicles.

In addition, the degradation determination process may be performed individually for the respective LFP cells (unit cells) or may be performed for a battery pack composed of a plurality of LFP cells.

What is claimed is:

1. A degradation determination device for a lithium iron phosphate ion (LFP) cell, comprising:
a charger/discharger that charges and discharges the LFP cell; and
a controller that controls the charger/discharger, wherein:
the controller executes a series of charge/discharge processes in which
the LFP cell is charged to a fully charged state using the charger/discharger, and
the LFP cell in the fully charged state is discharged using the charger/discharger until an open circuit voltage (OCV) of the LFP cell reaches a predetermined OCV of the LFP cell, the predetermined OCV uniquely representing a common battery capacity before and after degradation of the LFP cell, and an integrated current value of a discharge current during such discharge is acquired; and
the controller
executes the charge/discharge processes one or more times to acquire a variable battery capacity of the LFP cell based on one or more integrated current values acquired through the charge/discharge processes,
calculates a full charge capacity of the LFP cell by adding the variable battery capacity to the common battery capacity, and
determines degradation of the LFP cell based on the calculated full charge capacity of the LFP cell and an initial full charge capacity of the LFP cell.

2. The degradation determination device according to claim 1, wherein the controller executes the charge/discharge processes two or more times to acquire two or more integrated current values through the charge/discharge processes, and determines an average value of the two or more integrated current values as the variable battery capacity.

3. A vehicle comprising the degradation determination device according to claim 1, wherein the controller
executes the charge/discharge processes while the vehicle is parked, and
charges the LFP cell from a main battery mounted on the vehicle and discharges a current from the LFP cell to a load mounted on the vehicle in the charge/discharge processes.

4. A degradation determination method for an LFP cell, comprising:
performing a charge/discharge process including charging the LFP cell to a fully charged state using a charger/discharger, and discharging the LFP cell in the fully charged state using the charger/discharger until an OCV of the LFP cell reaches a predetermined OCV of the LFP cell, the predetermined OCV uniquely representing a common battery capacity before and after degradation of the LFP cell, and acquiring an integrated current value of a discharge current during such discharge;
acquiring a variable battery capacity of the LFP cell based on one or more integrated current values acquired by performing the charge/discharge process one or more times;
calculating a full charge capacity of the LFP cell by adding the variable battery capacity to the common battery capacity; and
determining degradation of the LFP cell based on the calculated full charge capacity of the LFP cell and an initial full charge capacity of the LFP cell.
